(19) United States
(12) Patent Application Publication
(10) Pub. No.: US 2023/0400534 A1
(43) Pub. Date: Dec. 14, 2023

(54) SENSOR USING A FIELD GRADIENT IN A GIVEN VOLUME

(71) Applicant: The University of Warwick, Coventry West Midlands (GB)

(72) Inventors: Gavin Morley, Coventry West Midlands (GB); Rajesh Patel, Coventry West Midlands (GB); Leiqing Zhou, Coventry West Midlands (GB)

(21) Appl. No.: 18/035,255

(22) PCT Filed: Nov. 4, 2021
(86) PCT No.: PCT/GB2021/052867

§ 371 Date: May 3, 2023

(30) Foreign Application Priority Data
Nov. 4, 2020 (GB) 2017477.7

(51) Int. Cl. G01R 33/07; G01R 33/04

(52) U.S. Cl. CPC G01R 33/07; G01R 33/04

(57) ABSTRACT

Sensor A device is disclosed. The device comprises a magnet (15) arranged to apply an inhomogeneous magnetic field (B) to a given volume (16) and a magnetometer having an active element (8) for sensing magnetic field in a volume which includes the given volume (16).

### FIELD

The present invention relates to a sensor, such as a magnetometer, electrometer or thermometer.

### BACKGROUND

A magnetometer which employs nitrogen-vacancy (NV) defects in diamond can be used as a sensor to detect weak magnetic fields. In many applications, it is desirable to have a remote, mobile sensor head and separate instrumentation. The sensor and instrumentation may be connected via an optical fibre or through free space. Fibre-coupled NV-diamond based magnetometers having sensitives up to 35 pT/√Hz have been demonstrated, whereas free space versions have achieved sensitives of 1 pT/√Hz for d.c. fields and 0.9 pT/√Hz for a.c. fields.

A review of magnetometry using nitrogen-vacancy defects in diamond is given by J. F. Barry et al.: “Sensitivity optimization for NV-diamond magnetometry”, Reviews of Modern Physics 92, 015004 (2020).

Reference is made to Shao-Chun Zhang et al.: “A high-sensitivity fiber-coupled diamond magnetometer with surface coating”, https://arxiv.org/abs/2102.12233, J. F. Barry et al.: “Optical magnetic detection of single-neuron action potentials using quantum defects in diamond”, Proceedings of the National Academy of Sciences of the United States of America, volume 113, pages 14133 to 14138 (2016) and T. Wolf et al.: “Subpicotesla Diamond Magnetometry”, Physical Review X, volume 5, page 041001 (2015).

Reference is also made to WO 2020/157497 A1 which describes a defect centre-based sensor.

### SUMMARY

According to a first aspect of the present invention there is provided a device comprising a magnet arranged to apply an inhomogeneous magnetic field (i.e., a spatially inhomogeneous magnetic field) to a given volume and a magnetometer having an active element for sensing magnetic field in a volume which includes the given volume. The active element may be used for sensing distortions of the inhomogeneous magnetic field caused by variations in shape and/or in composition of material.

Thus, the magnet may be used to increase spatial resolution of the magnetometer.

The inhomogeneous magnetic field may have a field gradient in the given volume that is between about 10⁻¹ and 10⁷ Tm⁻¹, preferably between about 10 and 500 Tm⁻¹.

The magnet may be a permanent magnet. The magnet may have a residual magnetisation of at least 0.01 T, for example, between about 0.1 T and about 2 T. The magnet may have a volume less than or equal to 2 mm³ or less than or equal to 0.1 mm³. The magnet may have a pointed pole for concentrating magnetic flux. For example, the magnet may be conical, frusto-conical, pyramidal, or frusto-pyramidal. The magnet may be an electromagnet, e.g., in the form of a solenoid or wire.

The magnet may be configured to apply a time-varying (i.e., AC) magnetic field. Using an AC magnetic excitation, currents can be induced in metals (which can be magnetic or non-magnetic) and the induced currents can produce magnetic fields which can be detected by the magnetometer. Using an inhomogeneous AC field may be used to sense damage (which may also be referred to as a “defect”) away from the near surface of the sample (for example, the far side of the sample). Thus, the approach can be used, for example, to identify corrosion on the inside of a pipe using the magnetometer on the outside of the pipe.

The device may further comprise a biasing magnet arranged to apply a bias magnetic field to the active element. The bias magnetic field can help improve magnetic sensitivity. The bias magnetic field is preferably uniform (i.e., homogeneous) across the active element.

The biasing magnet may be a permanent magnet. The biasing magnet may have a residual magnetisation of at least 0.01 T, for example, between about 0.1 T and about 2 T. The biasing magnet may have a volume equal to or greater than 1,000 mm³ or equal to or greater than 5,000 mm³.

The magnetometer may comprise a region of material which contains at least one defect centre. The material may be diamond and the defect centre(s) may be nitrogen vacancy centres. The magnetometer may be an optically-pumped atomic vapour cell magnetometer, a Hall effect magnetometer, a fluxgate magnetometer, a magnetoresistance magnetometer or a SQUID magnetometer.

According to a second aspect of the present invention there is provided apparatus comprising the device of the first aspect and a sample. The sample may be removable. The magnet is preferably arranged to apply the inhomogeneous magnetic field in a given volume of the sample and the magnetometer is arranged to sense the magnetic field in the given volume.

The apparatus may further comprise a controller (such as a microcontroller or computer system) configured to monitor the sensed magnetic field and, in response to detecting a pre-defined condition, to generate a trigger. The trigger may cause a message to be presented to a user.

According to a third aspect of the present invention there is provided an imaging system, comprising the device of the first aspect and a scanning stage for carrying the sample and moving the sample with respect to the active element. The sample and/or the sensor may be arranged to move in-plane (e.g., x-y plane). The sample and/or the sensor may be arranged to move out-of-plane (e.g., along a z-axis) so as to vary lift-off.

The imaging system may further comprise a computer system arranged to generate an image using signals from the magnetometer in dependence upon the position of the scanning stage.

According to a fourth aspect of the present invention there is provided apparatus comprising the imaging system of the third aspect and a sample. Movement of the scanning stage allows different parts of the sample to be sensed.

A distance s between the active element and the given volume is preferably less than 10 mm, more preferably less than 5 mm. The distance is preferably between 0 and 10 mm and more preferably between 0 and 5 mm.

According to a fifth aspect of the present invention there is provided a method comprising causing a magnet to apply an inhomogeneous magnetic field to a given volume of a sample, and sensing magnetic field in a volume including the given volume using an active element of a magnetometer. The magnetometer may be used to sense distortions of the inhomogeneous magnetic field caused by variations in shape and/or in composition of material.

The method may comprise bringing the sample and the active element together (e.g., by moving the sample and/or the active element) such that the sample and the active element are separated preferably by less than or equal to 10 mm, more preferably less than 5 mm. The distance is preferably between 0 and 10 mm, more preferably between 0 and 5 mm.

According to a sixth aspect of the present invention there is provided a device comprising a sensor which is not a magnetometer having an active element for sensing a field or physical quantity in a given volume in a sample, and a source and/or a sink arranged to apply an inhomogeneous field to the given volume or to change the physical quantity inhomogeneously in the given volume. The sensor may be used to sense distortions of the inhomogeneous field or physical quantity caused by variations in shape and/or in composition of material.

The field may be an electric field. The source may be an electrically charged region or a wire (for instance a coil or loop).

The physical quantity may be temperature and the source may be a heater. The sink may be a refrigerator.

The physical quantity may be a concentration.

By applying an inhomogeneous magnetic field from a magnet which has a linear dimension (e.g., a side) of x mm (for example, where x is 1 mm), it is possible to achieve a high spatial resolution for example as low as x mm or even lower in a plane parallel to a surface of a sample and 0.1 x (for example, 0.1 x=0.1 mm) or lower in a plane perpendicular to the surface. Structural damage in the sample distorts the inhomogeneous magnetic field and by detecting the distortion it is possible to reconstruct the damage profile by measuring the magnetic field with the magnetometer, such as by measuring shifts in the Zeeman splitting of defect centres. This can be used even when the magnetic material is covered by a non-magnetic material. The lift-off distance from the surface of the sample can be as high as 3 mm or more.

### BRIEF DESCRIPTION OF THE DRAWINGS

Certain embodiments of the present invention will now be described, by way of example, with reference to the accompanying drawings, in which:

FIG. 1 is a schematic diagram of sensor system which includes a sensor head, first and second permanent magnets, a microwave antenna, a laser, a signal delivery arrangement, a neutral density filter, a microwave source, a radio frequency source, a lock-in amplifier, and a balanced detector;

FIG. 2 is a schematic plan view of a microwave antenna arrangement for delivering microwaves and a pair of magnets for inducing Zeeman splitting;

FIG. 3 is a schematic side view of the microwave antenna arrangement and magnets shown in FIG. 2;

FIG. 4A is a plan view of a first sample in the form of a 316-grade stainless steel plate which includes damage (a slot defect having a rectangular perimeter and gradient depth profile);

FIG. 4B is a cross section of the plate shown in FIG. 4A taken along a line A-A′;

FIG. 5A is a plan view of a first sample in the form of a 316-grade stainless steel plate which includes different damage (a slot defect having a trapezoidal perimeter and a uniform depth profile);

FIG. 5B is a cross section of the plate shown in FIG. 5A taken along a line B-B′;

FIG. 6a is a plot of an optically-detected magnetic resonance (ODMR) signal from a lock-in amplifier output;

FIG. 6b is a plot showing dependence of ODMR sensitivity on input microwave power (squares) and modulation amplitude (circles)

FIG. 6c is a plot showing changes to lock-in amplifier voltage output whilst monitoring a fixed microwave frequency when the lift-off distance between a sensor head and a damage-free 316-grade stainless steel sample is changed for two differing sensitivity settings and lift-off is 0.2 mm for ΔHeight=0 mm;

FIG. 7a is a 2D-scan for the first sample shown in FIGS. 4A and 4B;

FIG. 7b shows experimental and COMSOL-simulated cross sectional profile using a Lorentzian fit to the scan shown in FIG. 7a;

FIG. 7c is a plot of full width at half maximum (FWHM) of the cross-sectional profile to the scan shown in FIG. 7a;

FIG. 7d is a 2D-scan for the second sample shown in FIGS. 5A and 5B;

FIG. 7e shows experimental and COMSOL-simulated cross sectional profile using a Lorentzian fit to the scan shown in FIG. 7d;

FIG. 7f is a plot of full width at half maximum (FWHM) of the cross-sectional profile to the scan shown in FIG. 7d;

FIG. 8a is a 2D-scan of the first sample shown in FIGS. 4A and 4B when covered with a first non-magnetic coating (1.5 mm of brass);

FIG. 8b is a 2D-scan of the second sample shown in FIGS. 5A and 5B when covered with a first non-magnetic coating (1.5 mm of brass);

FIG. 8c is a 2D-scan of the first sample shown in FIGS. 4A and 4B when covered with a second non-magnetic coating (2 mm of fibreglass);

FIG. 8d is a 2D-scan of the second sample shown in FIGS. 5A and 5B when covered with a second non-magnetic coating (2 mm of fibreglass);

FIG. 9 is an energy level diagram of a negatively-charged nitrogen-vacancy centre in diamond showing spin quantum number, vibronic levels, non-spin conserving transitions (in dash), and a 1042 nm infrared transition between the ¹A₁ and 1E energy levels, wherein parameter D is ˜2.87 GHz at room temperature;

FIG. 10a is an ODMR spectrum obtained using Supermagnete W-01-N and Q-25-25-13-N magnets;

FIG. 10b is an ODMR spectrum obtained using only a Supermagnete Q-25-25-13-N;

FIG. 10c is a plot of spectral density corresponding to the configurations in FIG. 10a and FIG. 10b;

FIG. 11a shows ODMR spectra with and without a 316-grade stainless steel sample,

FIG. 11b show the ODMR spectra shown in FIG. 11a in greater detail between 3000 and 3050 MHz for an outermost, right-hand side NVC resonance;

FIG. 11c shows ODMR spectra for a range of lift-offs;

FIG. 11d show the ODMR spectra shown in FIG. 11c in greater detail between 3000 and 3050 MHz for an outermost, right-hand side NVC resonance;

FIG. 11e shows ODMR spectra for different positions along a defect

FIG. 11f show the ODMR spectra shown in FIG. 11e in greater detail between 3027 and 3029 MHz for an outermost, right-hand side NVC resonance;

FIG. 12a is a 2D scan image of gradient depth a first sample;

FIG. 12b is a plot of change in LIA output voltage taken along the horizontal dashed line shown in FIG. 12a which runs parallel to the y-axis;

FIG. 12c are plot in LIA output voltage taken along the vertical dashed lines shown in FIG. 12d which runs parallel to the x-axis;

FIG. 12e is a 2D scan image of gradient width a second sample;

FIG. 12f is a plot of change in LIA output voltage taken along the horizontal dashed line shown in FIG. 12d which runs parallel to the y-axis;

FIG. 12c are plot in LIA output voltage taken along the vertical dashed lines shown in FIG. 12d which runs parallel to the x-axis;

FIG. 13 is plot of magnetic flux profile of a pair of bias fields simulated using COMSOL® software;

FIG. 14 illustrates a set-up for a COMSOL simulation shown in FIG. 13 using a gradient depth sample (for simplicity air space and mesh network have been ignored);

FIGS. 15a and 15b are first and second simulated 2D-scans of first and second 316-grade steel samples;

FIG. 16 is schematic view of a sensor, sample, sensed region and magnets.

### DETAILED DESCRIPTION OF CERTAIN EMBODIMENTS

### Introduction

The optically-detected magnetic resonance (ODMR) of nitrogen-vacancy centers (NVC) in diamond can be used as a magnetic sensor. Key strengths of NVC magnetometry are the high dynamic range, operation in wide temperature ranges, suitability for high radiation environments, and chemical inertness. The property of ODMR allows nanoscale resolution magnetometry, when employing single centers. Conversely, an ensemble of NVC allows for higher sensitivities at the expense of the spatial resolution with high sensitivities achieved for both DC and AC frequencies. A range of applications have been demonstrated from single neuron action potential detection to eddy-current-induced magnetic field detection of conductive samples for material analysis.

The identification of structural defects through the use of magnetic flux leakage (MFL) is a non-destructive testing technique that is among the most-used methods for yielding information about the nature of unknown defects in magnetic materials. MFL measurements involve magnetically saturating the target material. If there is no damage, the magnetic flux lines are unperturbed. If, however, there is a flaw magnetic flux leaks out of the material. MFL measurements have found applications in industries where the corrosion of magnetic material, such as steel, will eventually lead to significant material loss and in particular have been heavily utilized by the oil and gas industries in pipeline inspection gauges to minimize the need for costly excavations. Several different magnetic field sensors are employed in industry with the key technologies being induction coils, Hall probe sensors and magnetic flux gates with each offering distinct advantages and disadvantages. Hall sensors in particular have found great usage for MFL measurements due to their low cost, however these sensors suffer from voltage drift, even in the absence of a magnetic field and thus require compensation and offer limited sensitivity in comparison to other sensors. In addition, to effectively utilize the techniques of MFL the magnetic material under inspection must undergo magnetic saturation. This requirement sometimes makes it difficult to utilize the technique in the field.

Two quantum systems have been used recently for imaging structural damage in metals. The first used an atomic vapor cell to achieve a spatial resolution of 0.1 mm. However, this required the use of a sensitive commercial fluxgate magnetometer and 1 m electromagnet coils to null the background magnetic field. G. Chatzidrosose et al.: “Eddy-current imaging with nitrogen-vacancy centers in diamond”, Physical Review Applied, volume 11, 014060 (2019) demonstrated an NVC magnetometer design without microwaves (MW) to remove the problem of the ODMR microwaves interfering with the conductive materials under study. This required a relatively high external bias magnetic field of 102.4 mT supplied by a large water-cooled electromagnet.

The sensor herein described is based on ODMR of NVC but using microwave excitation means that only needs a low applied bias magnetic field from two permanent magnets. The sensor head design prevents microwave leakage with a small Faraday shield and does not use any compensation coils. Under the configuration herein described magnetic flux profile perturbations that arise in the permanent magnetic bias fields that are used to induce Zeeman splitting of the NVC are detected; a simulated 2D magnetic flux profile of the setup is hereinafter described in supplemental information section. These perturbations occur when the magnetic properties of the material are changed, such as by structural defects due to corrosion. This method of flux detection allows for reconstruction of the profile of defects in magnetic materials such as common steels. Furthermore, as the techniques employed do not require magnetic saturation, some of the limitations inherent to magnetic flux leakage measurements are avoided and hence a distinct advantage is offered compared to standard magnetic flux leakage measurements. It is still able to provide an accurate reconstruction of the examined defects in an unshielded environment. The fiber-coupled design with a small sensor head increases the flexibility for practical applications. The large lift-off of up to 3 mm allows this sensor to examine magnetic materials directly even when coated with a thick non-magnetic layer.

### EXPERIMENTAL DETAILS

R. L. Patel et al.: “Sub-nanoTesla magnetometry with a fiber-coupled diamond sensor” Physical Review Applied, volume 14, page 044058 (2020) describes a configuration achieving a sensitivity of 310±20 pT Hz in the frequency range of 10 to 150 Hz using an isotopically-purified ¹²C diamond. However, this configuration had poor spatial resolution for imaging. This problem is solved by introducing a 1 mm permanent magnet 2 mm from the diamond. While improving the spatial resolution (due to the steel experiencing an inhomogeneous bias field), the resulting inhomogeneous bias field on the diamond impairs the magnetic sensitivity. This means there is no need to use ¹²C diamond because the measurements are not limited by the natural abundance of ¹³C impurities. However, improving the sensitivity is still useful as it allows a higher lift-off from the steel.

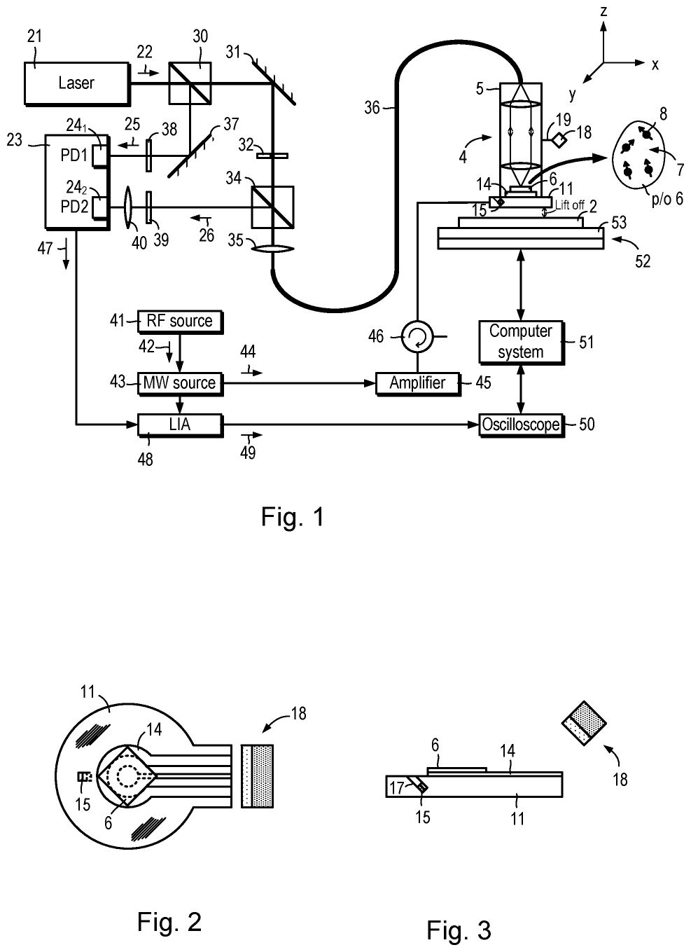

Referring to FIG. 1, a system 1 for inspecting a sample 2 is shown.

Referring also to FIGS. 2 and 3, the system 1 includes a sensor head 4 comprising a housing 5 which serves as a Faraday shield which houses an active element 6 in the form of a diamond containing an ensemble 7 of defect centres 8 in the form of NV-centres and a lens system 9 for delivering light to and from the active element 6. The active element 6 is mounted on a non-magnetic base 10 comprising an aluminium plate 11 coated in a dielectric layer (not shown) which support a microwave antenna 14 in the form of a copper loop. The non-magnetic base 10 may comprise another non-magnetic metal or metal alloy, a semiconductor or dielectric, such as silicon carbide or FR4. If the non-magnetic base 10 comprises a low conductivity semiconductor or a dielectric material then the dielectric material between the base and the antenna can be omitted.

The system includes a magnet 15 (“first magnet”) for generating an inhomogeneous magnetic field B in the sample 2 such that magnetic flux passes through a region of interest 16 (or “given volume”) in the sample 2. In this case, the magnet 15 takes the form of a permanent magnet which is embedded in the aluminium plate 11 via a hole 17 drilled in the plate 11. Another magnet 18 (“second magnet”) can be used for generating a bias magnetic field B_{B} for the magnetometer, i.e., for the defect centres, to bring the magnetometer to a suitable operating point. In this case, the second magnet 18 takes the form of a permanent magnet held in support 19 fixed to the exterior of the sensor head housing 4. In FIGS. 2 and 3, different shading is used to denote different poles of the magnets 15, 18. Electromagnet(s) may be used instead of permanent magnets(s).

It is possible to use the first magnet 15 without the second magnet 18. However, the second magnet 18 helps to control the chosen bias field on the magnetometer (which in this case is provided by the NV⁻ centres), and to reduce the magnetic inhomogeneity in the magnetometer. More than two magnets, which can have different shapes, can be used to help better achieve this.

The magnets 15, 18 supply a maximum magnetic field between 0.01 mT and 15 T, preferably between 0.1 and 1.5 T. The field gradient experienced by the region of interest 16 in the sample 2 from the inhomogeneous-field generating magnet 15 may be between 0.1 and 10⁷ Tm⁻¹, preferably between 10 and 500 Tm⁻¹. The magnetic flux B may be preferentially oriented from the inhomogeneous magnet towards the region of interest in the object of interest, but can be differently orientated as long as it reaches the region of interest with some inhomogeneity. As will be explained in more detail hereinafter, the active element 8, which in this case is provided by NV⁻ centre(s), may be used for sensing distortions of the inhomogeneous magnetic field B caused by variations in shape and/or in composition of material.

The system 1 includes instrumentation 20 including a laser 21 for generating an excitation signal 22, a signal detector 23 in the form of a balanced detector comprising first and second photodiodes 24₁, 24₂ for comparing a sample signal 25 and a response signal 26, and a signal delivery arrangement 29. The signal delivery arrangement 29 includes a beam sampler 30 for sampling the excitation signal 22, a first mirror 31, a stop 32 providing a pin hole, a dichroic mirror 34 which is used to separate the excitation signal 22 from the response signal 26, a lens 35 and an optical fibre 36. The sampled signal 25 is supplied to the first photodiode 24₁ via a second mirror 37 and a neutral density filter 38. The response signal 26 is supplied to the second photodiode 24₂ via a filter 39 and lens 40.

The instrumentation 20 includes an RF source 41 which supplies a RF signal (not shown) to a microwave source 43 which generates a microwave signal 44 which is supplied to the microwave antenna 13 via amplifier 45 and circulator 46.

The signal detector 23 generates an output signal 47 which is supplied, together with the microwave signal, to a lock-in amplifier 48 which generates a lock-in amplifier output signal 49. The lock-in amplifier output signal 49 is supplied to an oscilloscope 50 and a computer system 51. The sample 2 is held on a scanning stage 52 having an x-y bed 53.

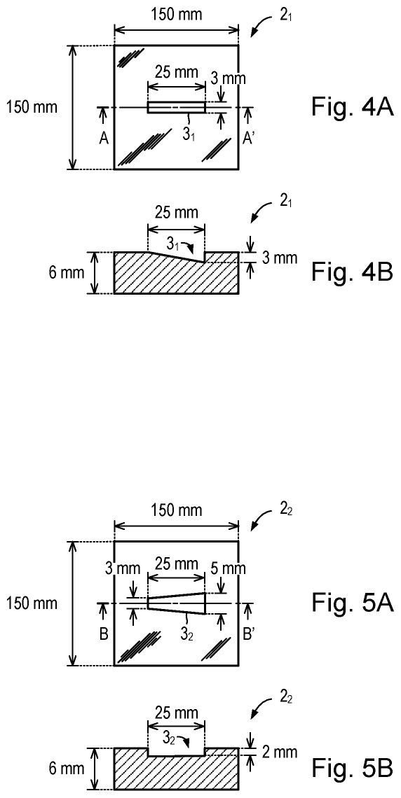

Referring to FIGS. 4a, 4b, 5a and 5b, experiments are conducted using first and second samples 2₁, 2₂ containing respective artificially-created slot defects 3₁, 3₂. Both samples 2₁, 2₂ are made of 316-grade stainless steel.

The first sample 2₁ contains a slot 3₁ with a 3 mm width with a gradient depth from 0 to 3 mm. The second sample 2₂ has a trapezoidal shape with a width ranging from 3 to 5 mm, and a fixed depth of 3 mm.

Both samples 2₁, 2₂ are mounted onto the x-y bed 53 of a scanning stage, whilst the sensor head 4 is affixed to a z-axis component stage (not shown). The scanning stage is used to enable two-dimensional scanning in the x- and y-axes with a different lift-off distance in the z-axis.

Data from the balanced output 47 are digitized by a Zurich MFLI DC-500 kHz lock-in amplifier (LIA) 48, with the MW frequency modulated.

Results and Discussion

The sensitivity of NVC magnetometers is highly dependent on the orientation of the magnetic fields relative to the NVC symmetry axis and the microwave delivery parameters, such as the microwave power, frequency modulation amplitude and modulation frequency.

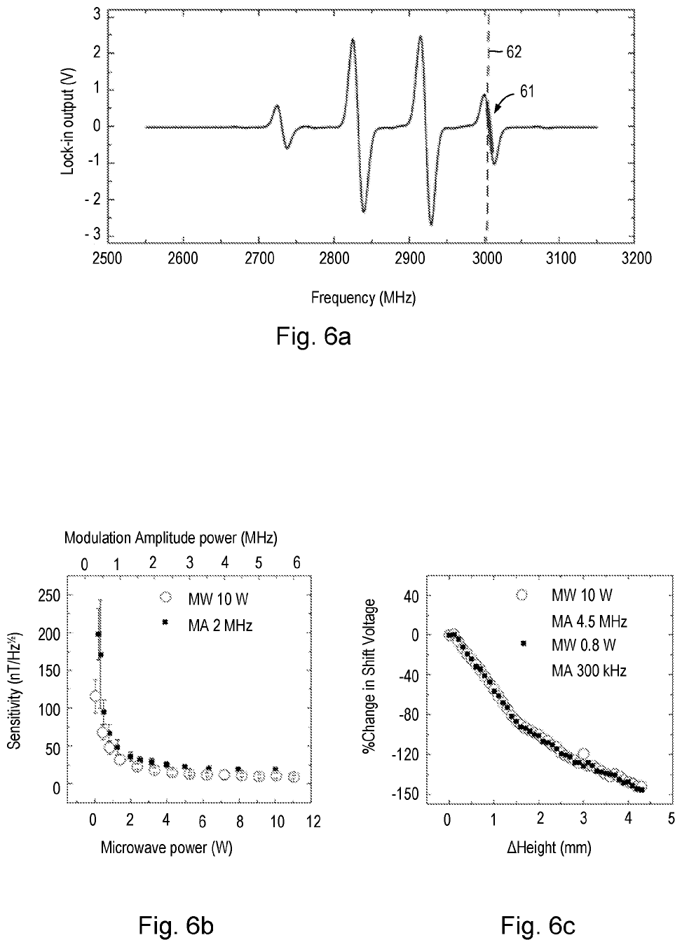

Referring to FIG. 6a, an NVC ODMR spectrum where the bias magnetic field is aligned along a <111> orientation is shown. A microwave power of 10 W was used with a frequency modulation amplitude of 4.5 MHz and a modulation frequency of 3.0307 kHz. These parameters were used for all measurements relating to structural defect quantification of the stainless-steel samples 2₁ (FIG. 4a), 2₂ (FIG. 5a).

A region 61 at about 3 GHz is the region of the ODMR feature where all scanning measurements of the 316-grade stainless steel plates 2₁ (FIG. 4a), 2₂ (FIG. 5a) were performed.

The optimum parameters of operation were found through variation of the microwave power between 0.2 W and 10 W at a fixed frequency modulation amplitude and modulation frequency. Conversely, the optimum frequency modulation amplitude was found through variation between 300 kHz and 6 MHz whilst the MW power and modulation frequency were fixed. For each parameter an ODMR spectrum was taken and linear fits applied around the central frequency of the ODMR feature in conjunction with a one second fast Fourier transform (FFT) of the voltage output of the central frequency.

Reconstruction of the image can involve mapping by scanning the sensor head with respect to the sample 2. The magnetic field strength is recorded using the magnetometer for one position of the sample and placing this value into a pixel in a 2D map before moving the steel with respect to the sensor and assigning the resulting magnetic field measurement to that new pixel. Alternatively, 1D or 3D scanning can be used to map out pixels in a line, or voxels for 3D imaging respectively. Alternatively, zero-dimensional mapping can be used as a function of time. In this case, no scanning in space occurs. Instead, the sensor monitors the behaviour of one pixel or voxel as a function of time.

Referring to FIG. 6b, the resulting sensitivity is shown, where each sensitivity is the mean of 96 FFTs. The errors are the standard deviation. The resonance of the NVC shifts when the value of the external magnetic field changes due to Zeeman shifts of the mₛ=±1 energy levels. Changes to the NVC resonance causes a change in the fluorescence and this correspondingly changes the voltage output of the LIA 48 (FIG. 1).

Referring to FIG. 6c, changes to the external magnetic field incident upon the NVC were caused by changes introduced to the distance between the sensor head 4 (FIG. 1) and the surface of the 316-grade stainless steel plates 2 (FIG. 1) in a damage-free area. The distance of the sensor head 4 (FIG. 1) from the surface of the ferromagnetic sample 2 (FIG. 1) was increased and the voltage changes to the LIA output 49 (FIG. 1) were found. Further details concerning the NVC ODMR changes are discussed in the supplementary information section. The reference point used is indicated by the dashed line 62 in FIG. 6a. This point corresponds to an LIA output 49 (FIG. 1) value of 0.6 V. Although any value can be used as the reference voltage provided it is along the linear region of the NVC ODMR resonance (and it is typical to use the zero-crossing point) 0.6 V was chosen as the starting reference voltage to allow for a higher lift-off distance in the measurements. Calibration was performed upon a blank area of the 316 stainless steel sample 2. In this instance, the reference frequency was chosen as the lowest value of the MW frequency of the highlighted feature in FIG. 6a. It is evident that the relationship between the Zeeman-induced change upon the defects is not linear with respect to the distance. This is attributed to the dipolar field pattern from the permanent magnets used. The trend of changes to the LIA output during the lift-off process are independent of the sensitivity. The trends are near identical regardless of the MW parameters used. This is expected as provided measurements are in the linear region of the ODMR feature, the differences should be entirely due to the bias magnets and their position relative to the active area of sensing within the diamond. As the differences caused are directly due to magnetic flux distortions, it is entirely possible to use this technique to map out the surface structure of magnetic materials.

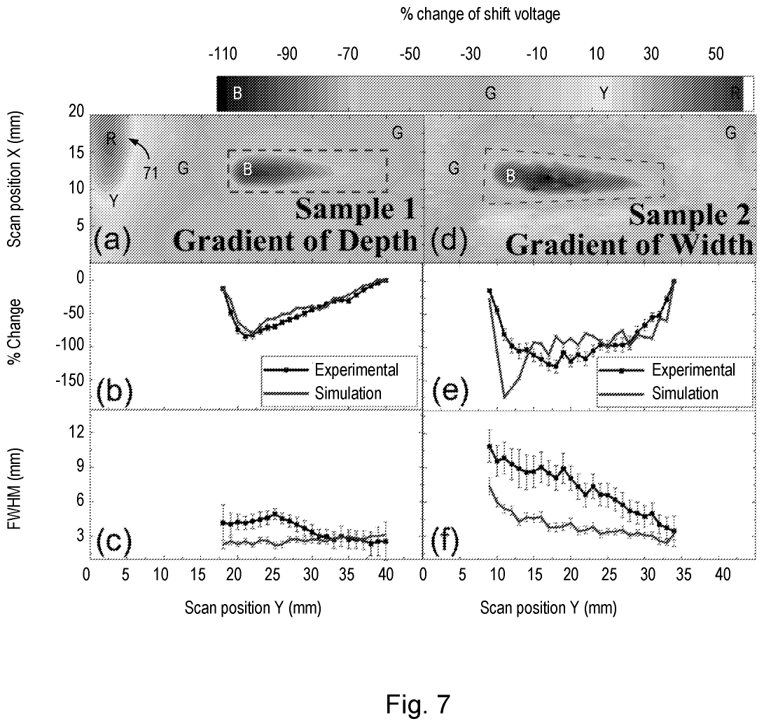

Referring to FIGS. 7a to 7f, the voltage change response of the magnetic field sensor caused by the steel samples surface structure are shown.

The scan resolution in the x and y axes were 1 mm. To prevent interference from the motors of the scanning stage 52 (FIG. 1), a dwell time of 1 s was implemented before the data acquisition process began. This led to a total scanning time of 2-3 seconds per point leading to a total scan time of approximately 66 minutes for a 20 mm by 45 mm scan. The total scan time for the maps shown in FIGS. 7a and 7d were 66 minutes. Both defects are mapped out and clearly visible as shown in FIGS. 7a and 7d.

The lift-off distance between the surface of the sample and the sensor head from the base of the aluminium PCB antenna 11 was 0.2 mm for all scans in both FIGS. 7a and 7d. The aluminium base 10 including the dielectric coating (not shown) may have a thickness of between 0.2 to 0.5 mm. Using the voltage difference and the calibration described in reference to FIG. 6c, it is possible to evaluate differences in the depth of the features. It is believed that the increase in normalized voltage output 71 in FIG. 7a in the top left corner is due to the larger magnet 18 (FIG. 1) being close to the sample edge.

FIG. 7a and FIG. 7d reveal differences in profile and show that a ferromagnetic sample can be differentiated based on its depth and width. Though the differences in the 2D profiles in FIG. 7a and FIG. 7d can identify the differing nature of the samples, to further highlight these differences and confirm the distinction between depth and width, the differences in the profile of the cross sections from FIGS. 7a and 7d were analysed by performing Lorentzian fits across the width spanned by the defect. It is expected for a sample where the depth changes, but not the width, that the magnitude of change to the LIA voltage output will increase across the length of the defect but this change will not be reflected in changes to the full width at half maximum (FWHM) which should remain fairly constant. This is demonstrated by FIG. 7c where the FWHM is for the most part constant while FIG. 7f shows that the amplitude increases in an almost linear fashion with increases with the depth of the defect. The rapid change in the shift voltage in FIG. 7b is due to the boundary of the defect edge where the depth change is maximum. In contrast, it is expected that the magnitude of change for a sample whose depth is unchanged will be constant across the length of the defect while the FWHM will change with a larger width resulting in a larger FWHM value. This is confirmed by FIG. 7f which shows a constant increase in the FWHM as the width of the defect increases but relatively constant voltage changes as shown in FIG. 7e. COMSOL® simulations of the experiment yield defect cross-sections and magnitude signals which are in overall agreement with the experiment. These results are shown in FIGS. 7b, 7c, 7e and 7f. The steel magnetic permeability used was 1.02 in the simulation.

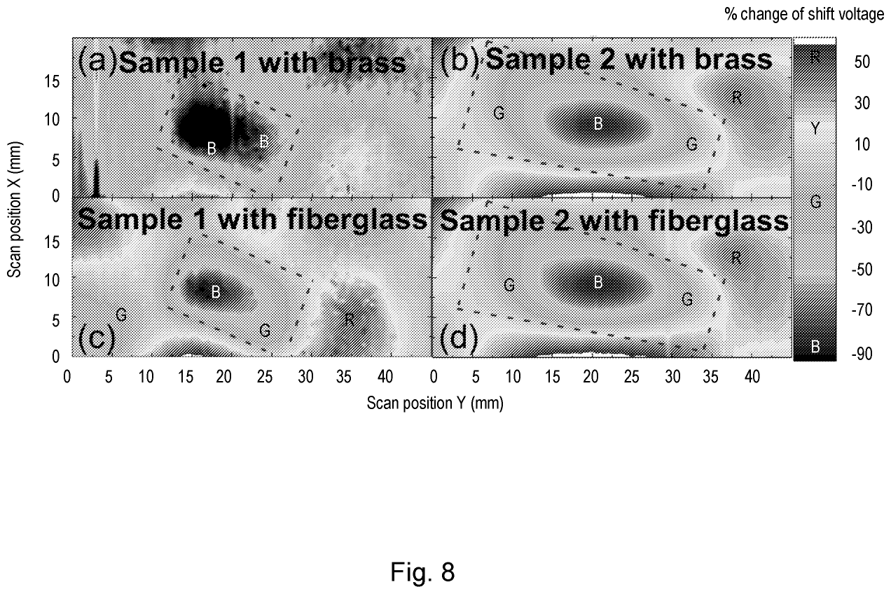

Steel corrosion under insulation is an important global problem and we demonstrate it is possible to map the defects even when they are covered by non-magnetic materials as shown in FIGS. 8a to 8d. The lift-off distance was 3 mm for all scans in FIGS. 8a to 8d when compared to those in FIGS. 7a to 7f, the larger lift-off means that the magnetic flux from the smaller magnet is incident over a larger area of the steel. This leads to a worse spatial resolution in the plane parallel to the sample surface: the x and y directions. In the z-axis, a 0.1 mm spatial resolution is achieved while for the x-axis and y-axis, about 1 mm is achieved which is believed to be limited by the 1 mm size of the small magnet. The minimum lift-off in the z-axis was set by the nominal resolution of the scanning stage in the z-axis. Increments lower than 0.1 mm were not possible. It may be possible to enhance the spatial resolution either through using a smaller magnet, or one with that is shaped to have a sharp point facing the steel.

### CONCLUSION

A method of imaging defects in magnetic materials using a compact sensor based on an ensemble of nitrogen-vacancy color centers in diamond is described herein. The sensor can be used to detect structural defects in magnetic materials and aid in their quantification even when covered with non-magnetic materials. This is particularly useful as corrosion under insulation is an important global problem. Reducing the size of the 1 mm cube bias magnet may improve the spatial resolution of our measurements. Furthermore, as the sensor head is based on diamond, the sensor is suitable for operation in radioactive environments and operation up to 300° C.

Supplemental Information

Nitrogen Vacancy Center Magnetometry Principles

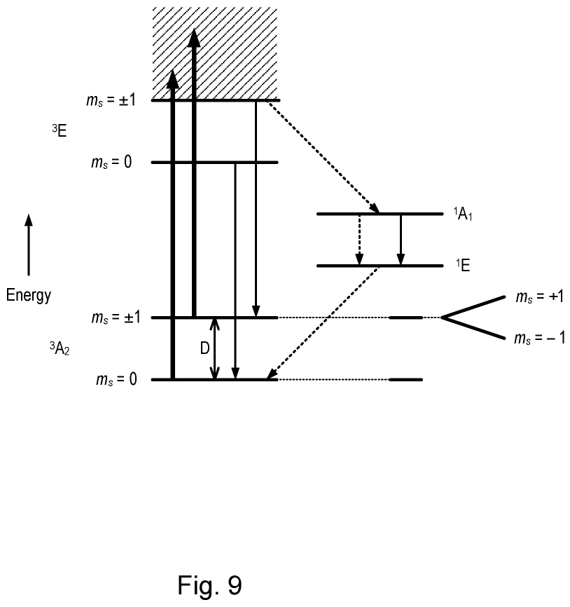

Referring to FIG. 9, the nitrogen-vacancy center (NVC) in diamond is a spin-1 color center with a zero-field splitting of 2.87 GHz. The system is comprised of two spin triplet states, the ground and excited state, ³A₂ and ³E respectively along with two singlet states, ¹A₁ and ¹E. The property of optically detected magnetic resonance (ODMR) allows spin-state readout through spin-dependent transitions which cause a reduction in the red fluorescence emitted by the NVC when in the mₛ=±1 when compared to the mₛ=0 states. This reduction is associated with transitions through an intersystem crossing through the ¹A₁ and ¹E states, which have longer lifetimes. The probability of inter-system crossing is higher for the ms=f 1 states. Optical excitation using a 532 nm laser allows spin initialization into the ³A₂ ms=0 state. These properties allow high signal-to-noise magnetic field detection when a bias magnetic field is applied to the NVC.

Experimental Detail

Referring again to FIG. 1, a Laser Quantum 532 nm Gem 21 was used to excite fluorescence from the NVC ensemble 7. The output laser power used was 1 W. A beam sampler 30 in the form of a Thorlabs BSF10-A and a neutral density filter 38 in the form of a Thorlabs ND10A were used to pick off 1% of the laser beam for laser noise cancellation using a balanced detector 23 in the form of a Thorlabs PDB450A. A 650 nm shortpass dichroic mirror 34 in the form of a Thorlabs DMSP650 was used to help separate the NVC fluorescence 26 and the laser excitation 22. The diamond 6 is mounted onto a custom-made aluminium microwave delivery antenna board 10 (a C.I.F AAT10) for mechanical stability which is a fixed to the sensor head.

Microwaves 44 are supplied by an Agilent N5172B with the carrier wave frequency modulated. This output was mixed with a 2.158 MHz sinewave 42 generated using an arbitrary function generator 41 in the form of a RSPro AFG21005 to simultaneously excite all three ¹⁴N hyperfine resonances. This microwave output 44 is then amplified using a 43 dB gain amplifier 45 in the form of a Mini-Circuits ZHL-16W-43-S+, and passed through a coaxial circulator 46.

A ˜1 mm hole 17 was drilled into the aluminium antenna 11 with an approximate 45° angle and 5 mm distance away from the microwave excitation loop 14. A 1 mm cube nickel-plated neodymium magnet 15 in the form of a Supermagnete W-01-N magnet was inserted into the hole 17. A second magnet 18 of dimensions 25 mm×25 mm×13 mm in the form of a Supermagnete Q-25-25-13-N magnet was used to reduce the strength of the magnet 15 nearest to the diamond to enhance the magnetometer sensitivity. The second magnet 18 was housed in a custom 3D printed holder which was affixed to the sensor head and enabled a 360° rotation of axes in two dimensions (those parallel to the x and y axes) and orientation control in the axis parallel to the z-axis allowing for arbitrary alignment of the magnetic field incident on the NVC ensemble 7.

The detection of damage in a magnetic material is possible as the magnetic flux profile change of the two magnets 15, 18 is monitored. The 1 mm cube magnet 15 is used a probe which injects magnetic flux into a magnetic material. When the magnetic properties of the material under study changes, this will affect the magnetic flux profile of the two magnets 15, 18. As the same magnets are also used to induce Zeeman splitting on the NVC ensemble 7, when there are any changes to the magnetic flux, it can be detected by the NVC ensemble 7. Due to the small size of the magnet 15 closest to the diamond 6, the field incident upon the NVC ensemble 7 is highly inhomogeneous. As the small magnet 15 is used as a probe to infer a material's magnetic properties the spatial resolution is directly correlated to the area of the sample that is magnetized. In addition, the spatial resolution is also affected by the volume excited by the 532 nm laser. For the excitation area, a beam waist of approximately 40 μm was measured, with the excitation in the z-axis being 0.24 mm.

Diamond Material Properties

The diamond 6 is a (100)-oriented high pressure high temperature (HPHT) sample, purchased from Element Six™, of dimensions 1.83 mm×1.85 mm×0.24 mm. The diamond 6 was laser-cut from a larger HPHT plate (not shown). The diamond 6 was selected as it has a lower nitrogen content than other similar HPHT samples. The diamond 6 was electron irradiated with 2 MeV electrons at a dose of 10¹⁸ cm⁻² at room temperature. The diamond sample was afterward annealed for 4 hours at 400° C., for 2 hours at 800° C. and 2 hours at 1200° C. At each step a 1-hour ramp was used between temperatures changes. This multistage annealing process was performed to encourage NVC formation whilst minimizing the presence of unwanted impurities. The diamond was mechanically polished on all six sides until an optical grade quality finish was achieved. The diamond was subsequently cleaned in a sulfuric acid (H₂SO₄) and potassium nitrate (KNO₃) solution for 60 minutes and then further cleaned for 20 minutes in H₂SO₄. The concentration of crystal defects in diamond was established though electron paramagnetic resonance (EPR), Fourier-transform infrared spectroscopy (FTIR) and ultraviolet-visible (UV-Vis) spectroscopy. UV-Vis data were taken using a Perkin Elmer Lambda 1050 spectrometer equipped with an Oxford Instruments Optistat cryostat. FTIR data were taken using a Perkin Elmer Spectrum GX FT-IR spectrometer. FTIR measurements were taken at room temperature. The concentration through EPR are [N^{o}ₛ]=31 ppm of single substitutional nitrogen and [NVC⁻]=1.8 ppm. FTIR established a concentration of [N^{s}ₒ]=38 ppm of single substitutional nitrogen and singly positively charged substitutional nitrogen [N⁺ₛ]=2.9 ppm. UV-Vis established a concentration of [NVC⁻]=4.3 ppm and [NVC^{o}]=0.4 ppm. The differences in NVC concentrations between EPR are UV-Vis are attributed to charge transfer effects.

Magnetometer Sensitivity

As the steepness of the slope of the LIA derivative output 49 (FIG. 2) of the ODMR spectra directly corresponds to the magnetic field sensitivity the data near the zero-crossing point of the outermost (111) resonances were determined by applying linear fits around the zero crossing. This provided a calibration with which to convert units of voltage into one of magnetic field. 160 fast Fourier transforms were taken when monitoring the zero crossing of the ODMR resonance.

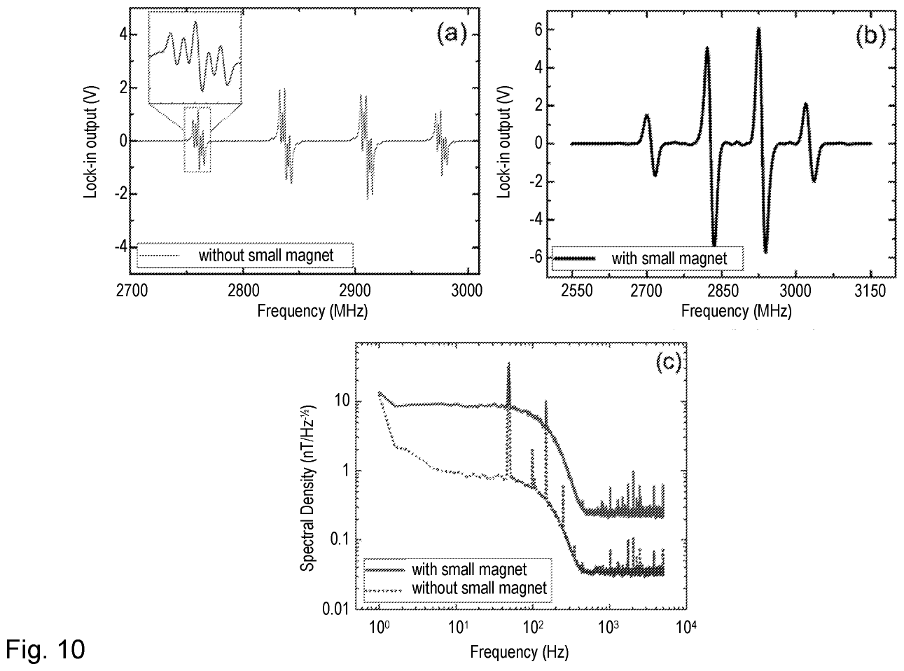

FIG. 10a shows the ODMR derivative spectrum under the two-magnet configuration whilst FIG. 10b shows the ODMR spectrum when using only the 25 mm×25 mm×13 mm magnet as the bias field for the NVC ensemble. The microwave parameters used for the experimental configuration corresponding to FIG. 10a were a microwave power of 10 W, a frequency modulation amplitude of 4500 kHz and a modulation frequency of 3:030 70 kHz, whilst the microwave parameters for FIG. 10b were a microwave power of 0.2 W, a frequency modulation amplitude of 350 kHz and a modulation frequency of 3:030 70 kHz. To quantify the broadening due to using the dual magnet arrangement ODMR spectra were taken in the absence of modulation with and without the 1 mm cube neodymium magnet. The NVC linewidth under the dual magnet arrangement was 26:75 MHz, whilst the NVC linewidth was 3:15 MHz when using only the 25 mm×25 mm×13 mm magnet 18 (FIG. 1). The NVC linewidths were obtained from ODMR spectra that were taken in the absence of any microwave modulation. For both ODMR spectra, the microwave parameters were optimized to yield the best sensitivity. The microwave frequency was swept in a selected range with a frequency step size of 20 kHz. The differences in sensitivity are shown in FIG. 10c. The sensitivity for the configuration corresponding to FIG. 10a is (9±1) nT/√Hz whilst it is (0.8±0.2) nT/√Hz for the configuration corresponding to FIG. 10b.

ODMR Spectrum Under Different Condition

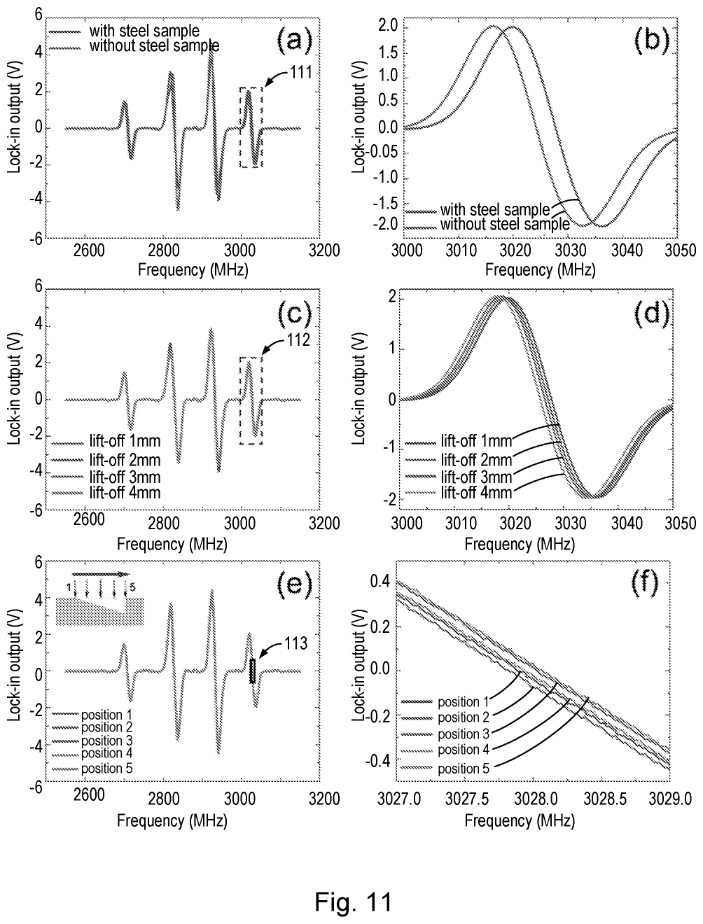

FIG. 11a shows ODMR spectra taken with and without a 316 stainless steel sample under the sensor head 4 (FIG. 1).

FIG. 11b shows the ODMR spectra when the steel sample is under inspection with different lift-off distances. The lift-off distances were between a range of 1-4 mm and 1 mm increments were used.

FIG. 11c shows the ODMR spectra when the sensor head placed at different position above the gradient depth sample. To highlight the resonance shifts the outermost NVC resonance are shown in FIGS. 11b, 11d and 11f, these correspond respectively to the dashed areas 111, 112, 113 in FIGS. 11a, 11c and 11e respectively. As is expected, the NVC ODMR resonances shifted correspondingly to the magnetic flux profile changes over the NVC ensemble which were caused by changing magnetic properties near the sensor head.

Scan Data Profile

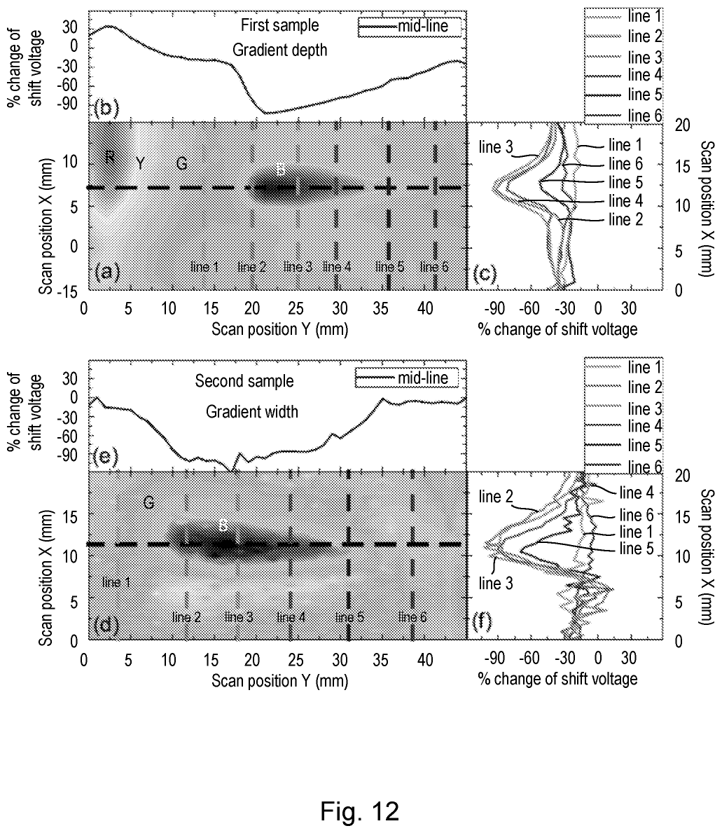

Referring to FIGS. 12a to 12c and FIGS. 12d to 12f, scan results of the gradient depth and gradient width sample are shown along with the cross-section profile.

Referring in particular to FIGS. 12b and 12e, when considering only the extent of the percentage change shift (relative to the 0.6 V reference) in the LIA output 49 (FIG. 1) differences are seen in the profiles for the gradient depth and gradient width samples, the differences in the depth are much clearer than that of the width.

To highlight the changes in the width, Lorentzian fits according to the profile shape are performed and it is possible to also to use Gaussian fits as described in Chatzidrosos et. al.: “Eddy-current imaging with nitrogen-vacancy centers in diamond”, Physical Review Applied 11, 014060 (2019). It was found that there was no distinct difference in the obtained full width at half maximum if a Lorentzian or a Gaussian profile is used for the fits. Thus, only the Lorentzian profiles are shown.

Finite Element Modelling Simulations

Simulations were performed COMSOL Multiphysics® simulations in the “Magnetic field, No current” mode.

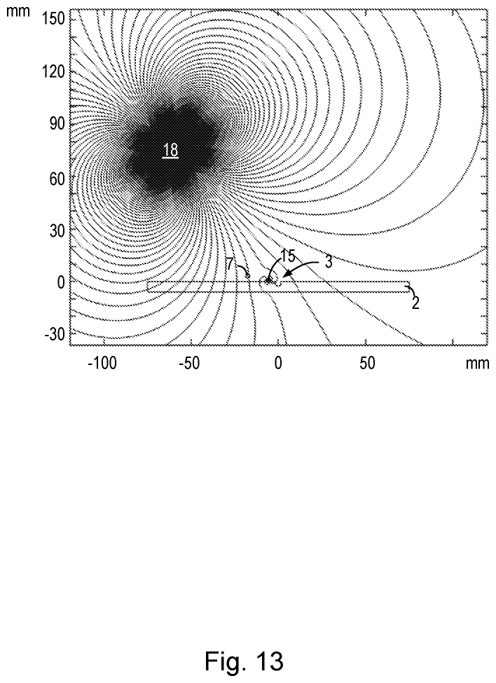

Referring to FIG. 13, a 2D magnetic flux profile using COMSOL® simulation is shown.

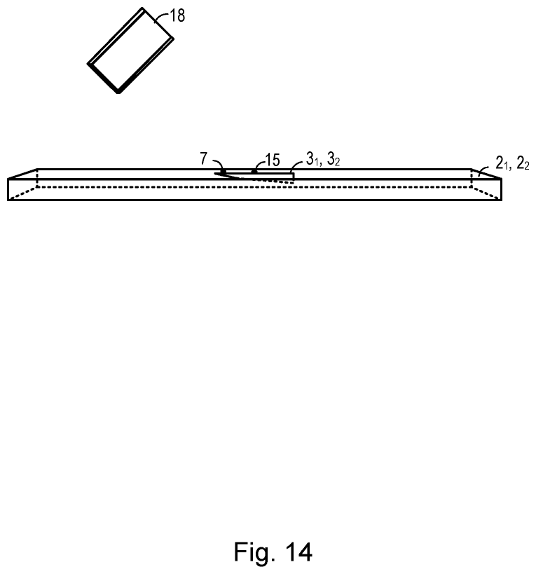

Referring also to FIG. 14, simulations of the damage 3₁, 3₂ in steel 2₁, 2₂ were three dimensional, with the geometry of the samples 2₁, 2₂ and defects 3₁, 3₂ hereinbefore described. The set-up is same as the experimental configuration.

The magnet grades used for the simulation are N45 magnet 15, for the 1 mm cube magnet, while the larger magnet 18 had a magnet grade of N42. Both magnets 15, 18 had a magnetic field permeability of 1.05.

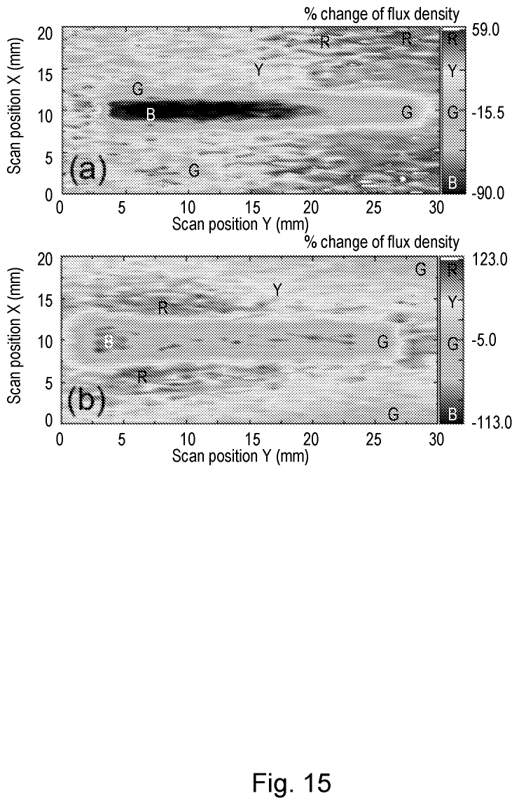

The step sweep for FIGS. 15a and 15b were 0.25 mm along the x-axis and 1 mm along the y-axis. The 316 stainless steel permeability was set to 1.02.

Dynamic Range

The dynamic range referred to hereinbefore is the extent of the linear region of lock-in amplifier derivative signal of the NVC ODMR.

It is desired to have a high dynamic range as the measurements using the NVC tend only to be performed when monitoring an NVC resonance. Application of a large magnetic field will shift the resonance such that it is no longer possible to gain any useful information regarding the nature of the defects in a magnetic material. In addition, having a high sensitivity is advantageous to provide a high signal-to-noise ratio for our measurements and achieve a higher lift off distance. For the measurements, the photon-shot-noise-limited sensitivity of the diamond-based magnetometer is given by:

$$η = \frac{4}{3 \sqrt{3}} \frac{h}{{g}_{NV} {μ}_{B}} \frac{Δν}{C \sqrt{{I}_{0}}} , \qquad ( 1 )$$

where Δv is the linewidth of an NVC resonance, C is the measurement contrast (the reduction in fluorescence when on resonance compared to when not on resonance), I₀ is the photon collection rate, g_{NV} is the g-factor (=−2.002), h is Planck's constant (6.626×10⁻³⁴ m²kgs⁻¹) and μ_{B} is the Bohr magneton (=9.274×10⁻³⁴ JT⁻¹).

It may be desirable (as it is here) to achieve a high sensitivity with a high dynamic range. To achieve a high dynamic range a large linewidth is required. This, however, degrades the sensitivity and thus reduces both the signal-to-noise and the achievable lift-off of the sensor from the surface of the material under inspection. For the system herein described, a compromise between the two was found through the use of highly inhomogeneous bias fields near to the diamond with a second magnet to reduce the inhomogeneous bias field incident upon the diamond. The highly inhomogeneous magnetic flux across the active sensing area of the diamond leads to a linewidth of 13.9±0.1 MHz. Through using the NVC gyromagnetic ratio (γ=28 Hz/nT) the dynamic range is estimated to be 0.5 mT. Significant benefits are expected with the implementation of a PID system that can track the NVC resonance which would extend the dynamic range whilst helping to minimise or even prevent any loss in sensitivity.

Other Magnetometers

Referring again to FIG. 1, the system 1 hereinbefore described uses NVC magnetometry for sensing the effect of damage in a magnetic sample on an inhomogeneous magnetic field. Other types of magnetometers may, however, be used. For example, the magnetometer may take the form of a vapour cell magnetometer (e.g., a spin-exchange relaxation-free magnetometer), a SQUID magnetometer, a Hall effect magnetometer, a magnetoresistance magnetometer or a fluxgate magnetometer.

A sensor can often be made more sensitive by making its sensing volume larger, but this typically degrades the best achievable spatial resolution. If the sensing volume is x mm then (in the absence of special adaptions) typically the best spatial resolution that can be achieved is also about x mm.

As described herein, an alternative approach is to use a small source of an inhomogeneous field (such as a magnet which acts a source of an inhomogeneous magnetic field) which is placed in the vicinity of the object under study. The shape and/or composition of the object under study distorts the inhomogeneous field, which can be detected by a suitable sensor. For example, a small magnet can provide an inhomogeneous magnetic field which can be distorted by a magnetic object in a way that depends on damage in the magnet object. Detecting the magnetic field with a more sensitive magnetometer can then map the shape of the damage by scanning the object with respect to the sensor which includes the small magnet.

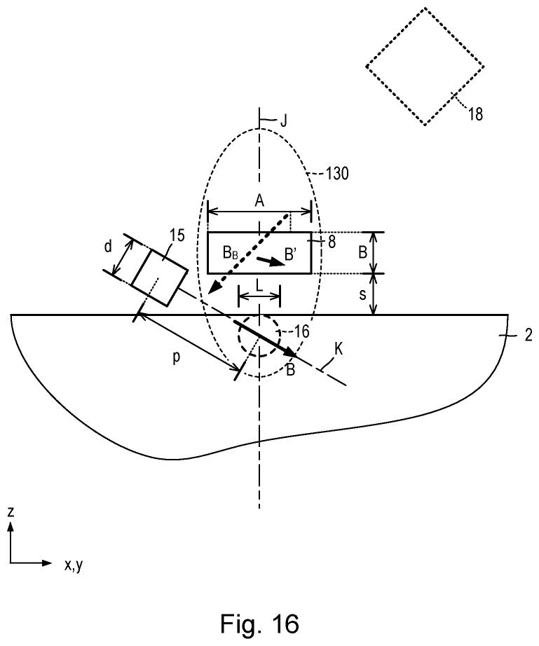

Referring to FIG. 16, better (i.e., smaller) spatial resolution is achieved not by using a smaller active element 8 (i.e., magnetic field sensing element), but by using a small magnet 15 and a small sensing distance s, i.e., the distance between the active element 8 and the sensed region 16, where the centre of the sensed volume 16 is generally defined by the intersection between a central axis J of the active element 8 and axis K of flux from the magnet 15. The dimensions A, B of the active element 8 may be much larger than the linear dimension(s) L of the sensed volume 16. This has the benefit that the magnetometer has a greater sensitivity due to the active element being larger. The sensed volume 16 forms part of a larger volume 130 (shown highly schematically) which the magnetometer senses, i.e., which contributes to the signal.

Generally, to achieve a resolution R, the size d of the magnet 15 and the sensing distance s should be reduced to the required resolution, in other words R≈d≈s and thus R≈L. The resolution R may be between 10 nm and 100 mm, for example, between 10 μm and 5 mm.

The centres of the small magnet 15 and the sensed region 16 are separated by a distance p which is sufficiently small that there is a sufficiently large magnetic field in the sensed region 16. The small magnet 15 need not be embedded in the sample 2, but can be outside the sample 2.

As explained earlier, the second magnet 18 need not be used, although the second magnet 18 and further magnets may be used to bias the active element 8 with a bias magnetic field B_{B} for proper operation.

Modifications

It will be appreciated that various modifications may be made to the embodiments hereinbefore described. Such modifications may involve equivalent and other features which are already known in the design, manufacture and use of defect centre-based sensors and magnetometers and component parts thereof and which may be used instead of or in addition to features already described herein. Features of one embodiment may be replaced or supplemented by features of another embodiment.

The material may be a material which exhibits ODMR, such as pentacene, and defects in or on the surface of crystals, amorphous solids, polycrystalline materials or epitaxial layers. Suitable materials include diamond, silica, zinc selenide and silicon carbide. The defect in diamond may be a NV⁻, silicon vacancy (SiV⁻ and SiV^{o}), germanium vacancy (GeV⁻) and tin vacancy (SnV⁻). The defect in quartz may be a self-trapped exciton. The defect in ZnS may be an A-centre acceptor. The defect in SiC may be a silicon vacancy defect and a neutral carbon-silicon divacancy in the 4H polytype and a divacancy (such as a chemically-bound silicon vacancy and carbon vacancy) in the 6H polytype.

Other forms of magnetometer can be used. The magnetometer may be optically or electrically probed. The magnetometer may take the form of a vapour cell magnetometer (for example a spin-exchange relaxation-free magnetometer), a SQUID magnetometer, a Hall effect magnetometer, a magnetoresistance magnetometer or a fluxgate magnetometer. Appropriate instrumentation is provided to read and process the magnetometer. Optically probing need not be used. For example, a signal may be obtained electrically. Microwave excitation need not be used. The instrumentation need not necessarily involve using lock-in amplifiers.

The inspection system (e.g., sensing system or imaging system) need not be based on sensing a magnetic field, but can be based on sensing a physical quantity, such as field, which can be measured by a sensor and for which there is a source (or sink) which can cause localised distortion. Examples of physical properties include an electric field, a temperature, and a concentration (for instance, of a gas or liquid). Thus, in the cases of an electric field, an electrometer can be used instead of a magnetometer and a system for generating an inhomogeneous electric field in the vicinity of the sample can be used which may contain one, two or more electric field sources such as charge regions, wires or coils. Appropriate instrumentation is provided to read and process the sensor.

The sensing system may be controlled by a controller, which may take the form of a microcontroller or a computer system. The sensing system need not include an oscilloscope.

Although claims have been formulated in this application to particular combinations of features, it should be understood that the scope of the disclosure of the present invention also includes any novel features or any novel combination of features disclosed herein either explicitly or implicitly or any generalization thereof, whether or not it relates to the same invention as presently claimed in any claim and whether or not it mitigates any or all of the same technical problems as does the present invention. The applicants hereby give notice that new claims may be formulated to such features and/or combinations of such features during the prosecution of the present application or of any further application derived therefrom.

1. A device comprising:
a magnet arranged to apply an inhomogeneous magnetic field (B) to a given volume; and
a magnetometer having an active element for sensing magnetic field in a volume which includes the given volume-.

2. The device of claim 1, wherein the magnet is a permanent magnet.

3. The device of claim 2, wherein the magnet has a residual magnetisation of at least 0.1 T.

4. The device of claim 2, wherein the magnet has a volume less than or equal to 2 mm³ or less than or equal to 0.1 mm³.

5. The device of claim 1, further comprising:
a biasing magnet arranged to apply a bias magnetic field to the active element.

6. The device of claim 5, wherein the biasing magnet is a permanent magnet.

7. The device of claim 6, wherein the biasing magnet has a residual magnetisation of at least 0.1 T.

8. The device of claim 6, wherein the biasing magnet has a volume equal to or greater than 1,000 mm³ or equal to or greater than 5,000 mm³.

9. The device of claim 1, wherein the magnetometer comprises a region of material which contains at least one defect centre.

10. The device of claim 9, wherein the material is diamond and the defect centre(s) is/are nitrogen vacancy centres.

11. The device of claim 1, wherein the magnetometer comprises a vapour cell magnetometer.

12. The device of claim 1, wherein the magnetometer comprises a Hall effect magnetometer.

13. The device of claim 1, wherein the magnetometer comprises a fluxgate magnetometer.

14. Apparatus comprising:
the device of claim 1; and
a sample;
wherein the magnet is arranged to apply the inhomogeneous magnetic field (B) in a given volume of the sample and the magnetometer is arranged to sense the magnetic field in the given volume.

15. The apparatus of claim 14, further comprising:
a controller configured to monitor the sensed magnetic field and, in response to detecting a pre-defined condition, to generate a trigger.

16. An imaging system, comprising:
the device of claim 1; and
a scanning stage for carrying the sample and/or the active element and for moving the sample and/or the active element with respect to each other.

17. The imaging system of claim 16, further comprising:
a computer system arranged to generate an image using signals from the magnetometer in dependence upon the position of the scanning stage.

18. Apparatus comprising:
the imaging system of claim 16; and
a sample;
wherein movement of the scanning stage allows different parts of the sample to be sensed.

19. The apparatus of claim 18, wherein a distance s between the active element and the given volume is less than 10 mm.

20. A method comprising:
causing a magnet to apply an inhomogeneous magnetic field (B) to a given volume of a sample; and
sensing magnetic field in the given volume using an active element of a magnetometer.

21. The method of claim 20, comprising:
bringing the sample and the active element together such that the sample and the active element are separated by less than or equal to 10 mm.

22. A device comprising:
a sensor which is not a magnetometer having an active element for sensing a field or physical quantity in a given volume in a sample; and
a source arranged to apply an inhomogeneous field (B) to the given volume or to change the physical quantity inhomogeneously in the given volume.

23. The device of claim 22, wherein the field is an electric field.

24. The device of claim 22, wherein the physical quantity is temperature.

25. The device of claim 22, wherein the physical quantity is a concentration.
